(19) United States
(12) Patent Application Publication
(10) Pub. No.: US 2025/0178979 A1
(43) Pub. Date: Jun. 5, 2025

(54) METAL-CERAMIC COMPOSITE

(71) Applicant: Heraeus Electronics GmbH & Co. KG, Hanau (DE)

(72) Inventors: Richard WACKER, Hanau (DE); Leszek NIEWOLAK, Hanau (DE); Stefanie STOICA, Hanau (DE); Daniel SCHNEE, Hanau (DE); Bastian SCHLÜTER, Hanau (DE)

(21) Appl. No.: 18/962,429

(22) Filed: Nov. 27, 2024

(30) Foreign Application Priority Data
Nov. 30, 2023 (EP) 23213373.6

(51) Int. Cl. C04B 41/88; C04B 41/00; C04B 41/45; H01L 23/15; H01L 23/29; H01L 23/31

(52) U.S. Cl. CPC C04B 41/88; C04B 41/009; C04B 41/4572; H01L 23/291; H01L 23/15; H01L 23/3121

(57) ABSTRACT

A metal-ceramic composite containing a ceramic substrate comprising a front side and a rear side and containing β-silicon nitride, and a metal coating on the front side of the ceramic substrate, wherein the metal coating comprises at least one recess, and a surface of the ceramic substrate is exposed by the recess.

### CROSS-REFERENCE TO RELATED APPLICATIONS

This application claims priority pursuant to 35 U.S.C. 119(a) to European Patent Application No. 23213373.6, filed Nov. 30, 2023, which application is incorporated herein by reference in its entirety.

### FIELD OF THE INVENTION

The present invention relates to a metal-ceramic composite which can be used as a ceramic circuit carrier in power electronics.

### BACKGROUND OF THE INVENTION

In power electronics, printed circuit boards must be designed for high currents as carriers for power components, such as MOSFETs, and be able to quickly dissipate waste heat.

Since ceramic materials, such as aluminum oxide, aluminum nitride, and silicon nitride, have a much higher thermal conductivity than polymers used to produce conventional printed circuit boards, ceramic circuit carriers are often used in power modules.

Ceramic substrates based upon silicon nitride have very high mechanical strength and at the same time high thermal conductivity and are therefore very suitable for applications in power electronics.

Silicon nitride can be present in a crystal structure known as “α-phase” or “β-phase.” These two phases differ in their X-ray diffraction patterns. The phase that is stable under normal sintering conditions is the β-phase (hereinafter also referred to as β-silicon nitride). Therefore, β-silicon nitride is usually present in the silicon nitride-based ceramic substrates.

β-silicon nitride contains needle-shaped crystallites. It is known that the mechanical properties or the thermal conductivity of the ceramic can be influenced by the alignment of these needle-shaped β-silicon nitride crystallites in the ceramic body. For example, it can be advantageous for the mechanical strength of the ceramic if the majority of the needle-shaped crystallites are oriented with their longitudinal axis substantially parallel to the ceramic surface, whereas it can be more advantageous for thermal conductivity if the majority of the needle-shaped crystallites are aligned with their longitudinal axis substantially perpendicular to the ceramic surface.

T. Okuno et al., “Si₃N₄ Substrates with Anisotropic Thermal Conductivity Suitable for Power Module Applications,” PCIM Europe digital days 2021; International Exhibition and Conference for Power Electronics, Intelligent Motion, Renewable Energy and Energy Management, Online, 2021, pp. 1-5, describe ceramic substrates that each contain β-silicon nitride, wherein the substrates differ in the alignment of the elongated β-silicon nitride crystallites. As the number of crystallites aligned with their longitudinal axis parallel to the thickness direction (i.e., perpendicular to the front or rear side) of the ceramic substrate increases, the intensity of the (101) reflection of the β-silicon nitride in the X-ray diffraction pattern also increases.

Ceramic substrates based on silicon nitride are described, for example, in the following publications:
N. Chasserio et al., “Ceramic Substrates for High-Temperature Electronic Integration,” Journal of Electronic Materials, Volume 38 (2009), pp. 164-174;
K. Hirao et al., “High Thermal Conductivity Silicon Nitride Ceramics,” Journal of the Korean Ceramic Society, Volume 49 (2012), pp. 380-384;
Y. Zhou et al., “Development of high-thermal-conductivity silicon nitride ceramics,” Journal of Asian Ceramic Societies, 3 (2015), pp. 221-229.

An overview of methods for the production of silicon nitride ceramics with different textures can be found in the following publication, for example:
X. Zhu und Y. Sakka, “Textured silicon nitride: processing and anisotropic properties,” Sci. Technol. Adv. Mater., 9, 2008, 033001.

Silicon nitride-based ceramic substrates, which show a good compromise between high mechanical strength and high thermal conductivity and can be used in electronic components, are commercially available.

A ceramic circuit carrier contains a ceramic substrate which is provided with a metal layer on at least one of its sides, usually on both sides. In the final module, the semiconductor components are applied to one of these metal layers, while the metal layer on the opposite side of the ceramic substrate is thermally conductively connected to a heat sink. The ceramic substrate electrically insulates the metal layers from each other.

Known to a person skilled in the art, a metallized ceramic substrate functioning as a ceramic circuit board is produced, for example, by bringing the front and rear side of the ceramic substrate into contact with a metal film (e.g., a copper or aluminum film) and bonding them together. The material bonding of the metal foils is achieved, for example, by eutectic bonding or active metal brazing (AMB). If the metal film is a copper film, eutectic bonding is also referred to as the DCB or DBC method (DCB: “direct copper bonding”; DBC: “direct bonded copper”). In the case of aluminum film, the term “DAB” (“direct aluminum bonding”) is also used for eutectic bonding. A metallized ceramic substrate produced using a DCB or AMB process is sometimes also referred to as a DCB substrate (alternatively: DBC substrate) or AMB substrate.

The metallization of silicon nitride substrates is usually carried out by active metal brazing.

Active metal brazes contain, in addition to a main component, such as Cu, Ag or Au, one or more elements that can react with the ceramic to form an adhesion-promoting reaction layer (see, for example, Chapter 8.2.4.3 (“Active metal brazing”), pages 203-204, in Brevier Technische Keramik, Verband der Keramischen Industrie eV, 2003, Fahner Verlag). Reactive elements, such as hafnium (Hf), titanium (Ti), zirconium (Zr), niobium (Nb), cerium (Ce), tantalum (Ta), and vanadium (V), are used. In the metallization of silicon nitride substrates by active metal brazing, the reaction layer contains, for example, a nitride, oxynitride and/or silicide of the reactive element (A. Pönicke et al., “Active metal brazing of copper with aluminum nitride and silicon nitride ceramics,” Keramische Zeitschrift, 63(5), 2011, 334-342).

The metal layer supporting the semiconductor components is structured (e.g., by etching). The structuring of AMB substrates can, for example, be carried out in a two-stage process, wherein, in a first step, the metal layer is first removed in defined regions (e.g., using a first etching solution), and then, in a second step, the adhesion-promoting layer resulting from the active metal brazing process is removed (e.g., using a second etching solution). By removing the metal layer in defined regions, the ceramic substrate is exposed again in these regions.

Modules based upon ceramic circuit carriers used in power electronics can be encapsulated as part of the packaging process, for example, by embedding the power module in a casting compound.

For example, embedding in a casting compound increases the electrical breakdown strength. In addition, the semiconductor components and metal conductor tracks are protected from humidity and mechanically stabilized.

In the regions exposed by the structuring, the ceramic substrate comes into direct contact with the casting compound. When operating a power module, significant temperature fluctuations can occur. Since ceramic materials and the casting compound usually have significantly different thermal expansion coefficients, these temperature fluctuations result in mechanical stresses at the interface between the ceramics and the casting compound. This in turn can result in the casting compound becoming at least partially detached from the ceramic substrate and in cavities forming. Humidity that penetrates these cavities can damage the power module. In addition, there may be a significant reduction in the electrical breakdown strength, at least locally.

As already mentioned above, ceramic substrates based upon silicon nitride are used as circuit carriers in power electronics due to their very high mechanical strength and high thermal conductivity. In order to make the most of their potential as circuit carriers, it would be desirable for there to be a high adhesive strength between the casting compound and the silicon nitride surface after embedding in a casting compound.

### SUMMARY OF THE PRESENT INVENTION

An object of the present invention is to provide a metallized silicon nitride-containing ceramic substrate, the exposed surface of which allows for the formation of a bond of high adhesive strength with a casting compound.

This object is achieved by a metal-ceramic composite containing
a ceramic substrate comprising a front side and a rear side and containing β-silicon nitride,
a metal coating on the front side of the ceramic substrate,
wherein the metal coating comprises at least one recess, and a surface of the ceramic substrate is exposed by the recess,
wherein the ceramic substrate satisfies the following condition at least in the region of the recess:

$${S}_{O - β SN} / {S}_{B - β SN} \geq 0.8 wherein$$

$${S}_{O - β SN} = {I}_{O - β SN} ( 1 \; 01 ) / [ 0.5 \times ( {I}_{O - β SN} ( 200 ) + {I}_{O - β SN} ( 120 ) ) ]$$

$${S}_{B - β SN} = {I}_{B - β SN} ( 1 \; 01 ) / [ 0.5 \times ( {I}_{B - β SN} ( 200 ) + {I}_{B - β SN} ( 120 ) ) ]$$

I_{O-βSN}(101), I_{O-βSN}(200) and I_{O-βSN}(120) are the relative peak heights of the (101), (200) and (120) reflection of the β-silicon nitride in an X-ray diffraction pattern measured under grazing incidence at 3° with Cu-Kα radiation, wherein the relative peak heights are normalized to the peak height of the (200) reflection.

I_{B-βSN}(101), I_{B-βSN}(200) and I_{B-βSN}(120) the relative peak heights of the (101), (200) and (120) reflections of the β-silicon nitride in an X-ray diffraction pattern, measured with Bragg-Brentano geometry and Cu-Kα radiation, wherein the relative peak heights are normalized to the peak height of the (120) reflection.

### DETAILED DESCRIPTION OF THE INVENTION

As mentioned above, the intensity of the (101) reflection of the β-silicon nitride in the X-ray diffraction pattern is influenced by the alignment of the elongate β-silicon nitride crystallites. As the number of crystallites aligned with their longitudinal axis parallel to the thickness direction (i.e., perpendicular to the front or rear side) of the ceramic substrate increases, the intensity of the (101) reflection and the intensity ratio of the (101) reflection to the (200) and (120) reflections of the β-silicon nitride in the X-ray diffraction pattern also increase. The peak height in the X-ray diffraction pattern, normalized to the height of a base peak, can be taken as a measure of the intensity of the reflections.

Grazing incidence X-ray diffraction is used to examine the structure of regions near the surface of a sample, whereas X-ray diffraction with Bragg-Brentano geometry provides structural information that is averaged over the entire irradiated volume of the sample.

In the scope of the present invention, it was surprisingly found that the adhesive strength of a casting compound on the ceramic substrate can be improved if the above-defined ratio (i.e., S_{O-βSN}/S_{B-βSN} 0.8) is fulfilled.

### For Example:

$${S}_{O - β SN} / {S}_{B - β SN} \geq 0.95$$

In one exemplary embodiment, the following relationship is fulfilled:

$$2.2 \geq {S}_{O - β SN} / {S}_{B - β SN} \geq 0.8$$

In another exemplary embodiment, the following relationship is fulfilled:

$$2.2 \geq {S}_{O - β SN} / {S}_{B - β SN} \geq 0.95$$

In another exemplary embodiment, the following relationship is fulfilled:

$$1.75 \geq {S}_{O - β SN} / {S}_{B - β SN} \geq 0.95$$

As will be described in more detail below, the ratio according to the invention (i.e., S_{O-βSN}/S_{B-βSN}≥0.8) can be adjusted in the ceramic substrate by irradiation with a pulsed laser beam, in particular an ultrashort pulse laser. This treatment appears to cause a relative increase in elongate β-silicon nitride crystallites oriented with their longitudinal axis substantially parallel to the thickness direction (i.e., perpendicular to the front or rear side) of the ceramic substrate in a region near the surface of the ceramic substrate. This in turn means that the value for S_{O-βSN} (i.e., I_{O-βSN}(101)/[0.5×(I_{O-βSN}(200)+I_{O-βSN}(120))]) shows a stronger increase than the value for S_{B-βSN} (i.e., I_{B-βSN}(101)/[0.5×(I_{B-βSN}(200)+I_{B-βSN}(120))]) and thus the ratio S_{O-βSN}/S_{B-βSN} increases.

In an exemplary embodiment, the ceramic substrate satisfies the following condition at least in the region of the recess:

0.4≤S_{O-βSN}≤2.0,
wherein S_{O-βSN} has the meaning given above.

In another exemplary embodiment, the following condition is fulfilled:

0.6≤S_{O-βSN}≤1.3

The X-ray diffraction pattern of β-silicon nitride and the indexing of the X-ray diffraction reflections in the diffractogram are known to a person skilled in the art. For example, using Cu-Kα radiation, the (101) reflection appears at a diffraction angle (20) of 33.7+/−1.0°, the (200) reflection at a diffraction angle (20) of 27.1+/−1.0° and the (120) reflection at a diffraction angle (20) of 36.1+/−1.0°.

Optionally, the ceramic substrate may contain one or more metal oxides. These were added, for example, as sintering aids during the production of the ceramic substrate. For example, the ceramic substrate contains one or more of the following oxides: one or more alkaline earth metal oxides such as magnesium oxide, one or more transition metal oxides (e.g., one or more rare earth oxides such as yttrium oxide or erbium oxide), a silicon oxide (e.g., SiO₂), or a silicate.

The ceramic substrate, for example, has a thickness in the range of 0.1 mm to 1.0 mm.

On the front side of the ceramic substrate, there is a metal coating which comprises at least one recess, so that a surface of the ceramic substrate is exposed by the recess. This metal coating is also referred to as structured metal coating. The semiconductor components can be attached to the structured metal coating.

Optionally, a metal coating is also available on the rear side of the ceramic substrate. This rear side metal coating can optionally also comprise at least one recess, through which a surface of the ceramic substrate is exposed. In order to achieve the most efficient heat dissipation possible, it may be preferable for the rear side metal coating not to comprise such a recess.

The metal coating present on the front side and optionally the rear side of the ceramic substrate is, for example, a copper coating or an aluminum coating. The metal coating has, for example, a thickness in the range of 0.05 mm to 1.5 mm, more preferably 0.2 mm to 0.8 mm.

If the metal coating is a copper coating, it has, for example, a copper content of at least 97 wt. %.

If the metal coating is an aluminum coating, it has, for example, an aluminum content of at least 97 wt. %.

The metal coating can be applied to the front side and optionally the rear side of the ceramic substrate using methods known to a person skilled in the art.

For example, a metal foil (e.g., a copper or aluminum foil) is bonded to the front side of the ceramic substrate by active metal brazing.

In active metal brazing, for example, a connection is made between the metal foil and the ceramic substrate using an active metal braze at a temperature of approximately 600-1,000° C. Due to their alloy composition, active metal brazes are able to wet non-metallic, inorganic materials such as ceramic substrates. In addition to a main component such as copper, silver and/or gold, active metal brazes also contain one or more active metals such as Hf, Ti, Zr, Nb, V, Ta or Ce, which can react with the bonding partner (e.g., the ceramic substrate).

Preferably, a reaction layer resulting from the active metal brazing is present between the metal coating and the front side of the ceramic substrate. The reaction layer contains, for example, one or more elements E_{RS}, selected from Hf, Ti, Zr, Nb, V, Ta, and Ce, preferably selected from Hf, Ti, Zr, Nb, and Ce, more preferably selected from Hf, Ti, and Zr. The element E_{RS} particularly preferred in the reaction layer is titanium. For example, the elements E_{RS} are present in the reaction layer in the form of a nitride, oxynitride, and/or silicide. For example, the reaction layer contains the elements E_{RS} in a total amount of at least 50 wt. %. For example, the reaction layer contains the nitrides, oxynitrides, and silicides of the elements E_{SR} in a total amount of at least 70 wt. %, more preferably at least 85 wt. %. In a power electronics semiconductor module, the migration of silver can cause problems. It may therefore be preferred that the reaction layer contains silver in a proportion of no more than 5 wt. %, more preferably no more than 1 wt. %, or is even silver-free.

Exposing a surface of the ceramic substrate takes place, for example, in several steps. First, the metal coating is removed, e.g., by etching, and the reaction layer formed during active metal brazing is exposed. The exposed reaction layer is then removed, e.g., by etching or laser ablation. Preferably, the exposed reaction layer is removed using an ultrashort pulse laser (e.g., an IR picosecond or femtosecond laser).

In order to electrically insulate the regions of the metal coating separated from one another by the recess, it would be sufficient to perform the material removal with the pulsed laser beam only until the electrically conductive material has been completely removed in the treated regions, but a structural modification of the β-silicon nitride phase on the surface of the ceramic substrate is avoided.

In the scope of the present invention, however, treatment with the ultrashort pulse laser not only exposes the ceramic substrate surface, but also structurally modifies the β-silicon nitride phase on the surface of the ceramic substrate. It has been found to be advantageous for setting the peak height ratios according to the invention if the pulsed laser beam is passed several times over the surface of the ceramic substrate, wherein the laser pulses have a pulse energy of at least 10 μJ, for example.

In the scope of the present invention, it is also possible to first expose the ceramic substrate surface by a single or multi-stage etching process and then treat the exposed ceramic substrate surface with the ultrashort pulse laser (e.g., an IR femto- or picosecond laser) until the peak height ratio according to the invention is realized.

However, for reasons of process efficiency, it may be preferable to use the pulsed laser beam for both exposure of the ceramic substrate surface and structural modification of the (3-silicon nitride phase on the surface of the ceramic substrate.

The region of the recess in which the ceramic substrate exhibits the peak height ratio according to the invention comprises, for example, at least 50%, more preferably at least 70% of the surface of the ceramic substrate exposed by the recess, or may even comprise substantially the entire surface of the ceramic substrate exposed by the recess.

An exposed surface of the ceramic substrate which fulfills the peak height ratio according to the invention results in improved adhesive strength of a casting compound to the ceramic substrate. In addition, the metal-ceramic composite according to the invention also has a high mechanical strength.

The present invention also relates to a semiconductor module, containing the metal-ceramic composite described above one or more semiconductor components.

Preferably, the semiconductor module also contains a casting compound, wherein the casting compound contacts the surface of the ceramic substrate of the metal-ceramic composite exposed by the recess.

Casting compounds for electronic components are known to a person skilled in the art. The casting compound contains, for example, a polymer (e.g., a thermoplastic or thermosetting polymer). For example, the casting compound contains an optionally cured epoxy resin or silicone resin, a polyurethane, or an inorganic cement (e.g., a phosphate cement).

### Measurement Methods

### Determination of the Peak Heights of Diffraction Reflections

X-ray diffraction measurements were carried out in two arrangements to determine the peak heights of the diffraction reflections.

In an initial measurement, the so-called Bragg-Brentano geometry was used. The peak heights of the reflections (101), (200) and (120) were determined in the diffractogram recorded with this geometry. The peak heights were normalized to the peak height of the (120) reflection.

A further measurement was carried out under a grazing incidence (3). The peak heights of the reflections (101), (200) and (120) were also determined in the diffractogram measured under grazing incidence. The peak heights were normalized to the peak height of the (200) reflection.

Diffractometer: Stoe & Cie GmbH, 2-circuit X-ray powder diffractometer, type Stadi P
Focusing: Bragg-Brentano geometry or grazing incidence angle (30) with secondary monochromator and scintillation counter
X-ray tubes: Copper anode
Wavelength: 1.54060 Å Cu-Kα
Operating voltage: 40 kV
Operating current: 30 mA
Measuring range: 2Theta: 5°-1000 with 0.02° step; Omega: 2.5°-50° 0.01 step
GI measuring range: 2Theta: 5°-100° with 0.03° step; Omega: 3°
Time/Step: 10 s

The diffractometer is adjusted and calibrated using the NIST standard Si (640d). The samples for the XRD measurement were cut out in the region of the exposed ceramic substrate in the form of 20×20×0.23 mm platelets.

### Composition of the Adhesion-Promoting Layer

The composition of the adhesion-promoting layer is determined by energy-dispersive X-ray spectroscopy (EDX) coupled with scanning electron microscopy (SEM-EDX).

In SEM-EDX, a focused primary electron beam is guided (scanned) over the sample surface point by point. The scattered electrons are detected using a detector, wherein the number of electrons per pixel results in a microscopic image of the sample surface in grayscale. In addition, the primary electron beam excites the sample to emit characteristic X-ray radiation, and the elements in the sample and their weight proportion can be determined by analyzing the energy spectrum using an EDX detector. For the examination, for example, a scanning electron microscope (JSM-6060 SEM, JEOL Ltd) with a silicon drift EDX detector (NORAN, Thermo Scientific Inc) and analytical software (Pathfinder Mountaineer EDS System, for example Version 2.8, Thermo Scientific Inc) are used. For scanning electron microscopy, the following settings are used: magnification: 1000-fold, acceleration voltage=15 kV, working distance=10 mm, spot size (50-60) (set to reach 25%+/−5% of the dead time of the EDX detector). The EDX spectrum was detected using the following settings of the EDX detector: live time=30 s, rate=auto, low energy cutoff=100 keV, high energy cutoff=auto (per SEM acceleration voltage).

By means of SEM-EDX, the composition of the adhesion-promoting layer can be determined both qualitatively (detection of certain elements and phases, e.g., a metal nitride phase present in the adhesion-promoting layer) and quantitatively. For example, the measurement is carried out at at least 10 points on the adhesion-promoting layer.

### EXAMPLES

Five silicon nitride ceramic substrates from the same product batch were used for the examples. The silicon nitride is substantially present in the β-phase. The ratio S_{O-βSN}/S_{B-βSN} was determined for each of these substrates. The starting substrates had substantially identical values for the S_{O-βSN}/S_{B-βSN} ratio.

S_{O-βSN}/S_{B-βSN} of the starting substrates: 0.63+/−0.02

Four of five silicon nitride substrates were metallized by identical active metal brazing processes under the conditions described below.

On one of the sides of the ceramic substrate, an active metal brazing paste was applied by screen printing on an area measuring 168 mm×130 mm and pre-dried for 15 minutes at 125° C. The active metal brazing paste consisted of 67 wt. % copper powder, 19.8 wt. % tin powder, 3.7 wt. % titanium hydride and 9.5 wt. % of an organic vehicle. The paste thickness after pre-drying was 25+/−5 μm. Subsequently, a copper film made of oxygen-free, highly conductive copper with a purity of 99.99% and dimensions of 170 mm×132 mm×0.3 mm was placed on the pre-dried paste. The resulting arrangement was then turned over, the paste was similarly applied to the opposite side of the ceramic substrate by screen printing, pre-dried and fitted with a copper film to obtain a sandwich arrangement. The sandwich arrangement was weighted with a weight of 1 kg, fired at a maximum temperature of 910° C. for 20 minutes, and then cooled to room temperature to obtain an unstructured metal-ceramic composite. Due to the production by active metal brazing, an adhesion-promoting reaction layer is present between the metal coating and the ceramic substrate. This contains titanium (e.g., in the form of a nitride).

Each of the four metal-ceramic composites was subjected to a first structuring process using an etching solution containing CuCl₂. The metal coating in the etched regions on the front side of the ceramic substrate was substantially completely removed. However, the reaction layer resulting from the active metal brazing process was not removed by the CuCl₂-containing etching solution.

In comparative example VB1, the exposed reaction layer was removed with an etching solution containing ammonium fluoride, fluoroboric acid, and hydrogen peroxide.

In examples EB1 to EB3 according to the invention, the exposed reaction layer was removed by laser treatment with a pulsed laser beam from an IR picosecond laser. The energy of the laser pulses was at least 12.5 μJ. In example EB1, the exposed reaction layer was scanned only once with the pulsed laser beam along the specified scan lines. In the examples EB2 and EB3, the scan lines were scanned twice with the laser beam, wherein a higher pulse energy was used in EB3 than in EB2.

S_{O-βSN}, S_{B-βSN} and the ratio S_{O-βSN}/S_{B-βSN} were measured for the exposed ceramic surfaces of the examples EB1 to EB3 according to the invention and the comparative example VB1. Subsequently, a casting compound was applied to each of the exposed ceramic surfaces, and the adhesive strength was determined.

A casting compound was also applied to the silicon nitride starting substrate, which was not metallized, and the adhesive strength was determined (comparison example VB0).

The adhesive strength was determined as follows:

To determine the adhesion of a casting compound (silicone), two plates (size of the plates: 20×20×0.32 mm) were cut out of each of the exposed regions of the corresponding ceramic substrate. The two plates, which were taken from the same ceramic substrate, were then bonded to form a test specimen by means of Sylgard 527 silicone. The overlap of both plates was 1 cm, so that the adhesive surface was always 2 cm². The silicone was cured in air for 2 hours at 125° C. Each test specimen was compressed with a weight of 50 g to produce a uniformly thin silicone layer.

The test specimens thus produced were tested for shear strength (testing machine: model zwicki500, ZwickRoell GmbH & Co. KG). The maximum shear force was determined in each case.

The results are summarized in the following table 1.

TABLE 1
S_{O-βSN}, S_{B-βSN} and the ratio S_{O-βSN}/S_{B-βSN}
of the silicon nitride ceramics and the adhesive strength
between the silicon nitride surfaces and a casting compound

| | | | | Maximum adhesive |
|---|---|---|---|---|
| Example | S_{B-βSN} | S_{O-βSN} | S_{O-βSN}/S_{B-βSN} | strength [N] |
| VB0 | 0.59 | 0.37 | 0.63 | 2.9 |
| VB1 | 0.51 | 0.36 | 0.71 | 2.8 |
| EB1 | 0.61 | 0.52 | 0.85 | 5.4 |
| EB2 | 0.65 | 0.70 | 1.08 | 15.1 |
| EB3 | 0.73 | 0.91 | 1.25 | 19.1 |

The treatment of the silicon nitride surface with the pulsed laser caused a structural modification of the β-silicon nitride phase on the surface of the ceramic substrate, as evidenced by the change in the intensity ratio of the (101) reflection to the (200) and (120) reflections.

This treatment appears to cause a relative increase in elongate β-silicon nitride crystallites oriented with their longitudinal axis substantially parallel to the thickness direction (i.e., perpendicular to the front or rear side) of the ceramic substrate in a region near the surface of the ceramic substrate. This in turn means that the value for S_{O-βSN} shows a greater increase than the value for S_{B-βSN} and therefore the ratio S_{O-βSN}/S_{B-βSN} increases.

The silicon nitride ceramics that fulfill the condition according to the invention, i.e., S_{O-βSN}/S_{B-βSN}≥0.8, show significantly better adhesive strength with regard to an applied casting compound.

1. A metal-ceramic composite, containing
a ceramic substrate comprising a front side and a rear side and containing 3-silicon nitride,
a metal coating on the front side of the ceramic substrate,
wherein the metal coating comprises at least one recess, and a surface of the ceramic substrate is exposed by the recess,
wherein the ceramic substrate satisfies the following condition at least in the region of the recess:
$${S}_{O - β SN} / {S}_{B - β SN} \geq 0.8 wherein$$
$${S}_{O - β SN} = {I}_{O - β SN} ( 1 \; 01 ) / [ 0.5 \times ( {I}_{O - β SN} ( 200 ) + {I}_{O - β SN} ( 120 ) ) ]$$
$${S}_{B - β SN} = {I}_{B - β SN} ( 1 \; 01 ) / [ 0.5 \times ( {I}_{B - β SN} ( 200 ) + {I}_{B - β SN} ( 120 ) ) ]$$
I_{O-βSN}(101), I_{O-βSN}(200) and I_{O-βSN}(120) are the relative peak heights of the (101), (200) and (120) reflection of the β-silicon nitride in an X-ray diffraction pattern measured under grazing incidence at 3° with Cu-Kα radiation, wherein the relative peak heights are normalized to the peak height of the (200) reflection,
I_{B-βSN}(101), I_{B-βSN}(200) and I_{B-βSN}(120) the relative peak heights of the (101), (200) and (120) reflections of the β-silicon nitride in an X-ray diffraction pattern, measured with Bragg-Brentano geometry and Cu-Kα radiation, wherein the relative peak heights are normalized to the peak height of the (120) reflection.

2. The metal-ceramic composite according to claim 1, wherein:
$$2.2 \geq {S}_{O - β SN} / {S}_{B - β SN} \geq 0.8$$

3. The metal-ceramic composite according to claim 1, wherein the following condition is fulfilled:
0.4≤S_{O-βSN}≤2.0,
wherein S_{O-βSN} has the meaning given in claim 1.

4. The metal-ceramic composite according to claim 1, wherein the metal coating is a copper or aluminum coating.

5. The metal-ceramic composite according to claim 1, wherein a reaction layer is present between the ceramic substrate and the metal coating, wherein the reaction layer contains one or more elements E_{RS} selected from Ti, Hf, Zr, Nb, V, Ta, and Ce.

6. A semiconductor module, containing the metal-ceramic composite according to claim 1, one or more semiconductor components.

7. The semiconductor module according to claim 6, further containing a casting compound, wherein the casting compound contacts the surface of the ceramic substrate of the metal-ceramic composite exposed by the recess.
